(19) United States
(12) Patent Application Publication
(10) Pub. No.: US 2012/0312354 A1
(43) Pub. Date: Dec. 13, 2012

(54) SOLAR MODULE AND PHOTOVOLTAIC ARRAY

(76) Inventor: Thomas BUETTNER, Jena (DE)

(21) Appl. No.: 13/491,295

(22) Filed: Jun. 7, 2012

(30) Foreign Application Priority Data
Jun. 8, 2011 (DE) 102011077227.8

(51) Int. Cl. H01L 31/05; H01L 31/048

(52) U.S. Cl. 136/251; 136/244

(57) ABSTRACT

A solar module having a plurality of solar cells connected in the form of a string, and having externally accessible string connections, the string connections and two earth contacts being developed as plug-in contacts integrated into the solar module in mechanically fixed manner, and the earth contacts being connected via an earth line integrated into the solar module.

### CROSS REFERENCE

The present application claims the benefit under 35 U.S.C. §119 of German Patent Application No. DE 102011077227.8 filed on Jun. 8, 2011, which is expressly incorporated herein by reference in its entirety.

### FIELD OF THE INVENTION

The present invention relates to a solar module having a plurality of solar cells interconnected in the form of a string, and having string connections that are accessible from the outside. In addition, it relates to a photovoltaic array having a plurality of solar modules which are electrically connected to each other.

BACKGROUND INFORMATION

Photovoltaic modules (PV modules), often also referred to as solar modules, contain solar cells, or photoelectrically active layers, which convert light into electrical current. They are able to be electrically contacted in order to carry away the generated electrical energy or in order to interconnect a plurality of PV modules so as to form a larger array. The PV modules usually have a connection box for this purpose.

FIG. 1A through 1D schematically illustrate different conventional connection boxes or cable configurations. FIG. 1A schematically shows a connection box 3 having two connection contacts 3a and 3b on a solar module 1. FIG. 1B schematically shows a modified connection box 13, which has two externally mounted plug components or jacks 13a, 13b on a solar module 11 for connecting power supply lines. FIG. 1C shows a solar module 21 having a connection box 23, to which two connection cables 25a, 25b are fixedly connected, which have at their particular ends a plug or a jack (not denoted specifically). FIG. 1D finally shows a solar module 31 having two connection boxes 33a, 33b, to which a connection cable 35a, 35b is connected, which once again has a plug or jack (not denoted specifically) at its end.

FIG. 2A through 2D show different possibilities for connecting solar modules to a load, i.e., a consumer or energy store or a network feeder, in the form of block diagrams. FIG. 2A shows the direct interconnection of an individual solar module 1 and a load 7; FIG. 2B shows the series connection of two solar modules la and lb to a load 7; FIG. 2C shows the parallel connection of two solar modules 1a, 1b to a load 7; and FIG. 2D shows a mixed series and parallel interconnection of six solar modules 1, which jointly form a photovoltaic array 10, to a load 7.

### SUMMARY

In accordance with the present invention, deviating from the currently used concept of providing a separate connection box on the solar module, the string connections are fixedly integrated as plug contacts into the actual module. Furthermore, the present invention may fixedly integrating two earth contacts as plug contacts in the same manner and to connect them via an earth line which is likewise integrated into the module.

In one development of the present invention, a section of the earth lines is formed by a metallic frame part of the solar module.

In another development, a bypass line having an externally accessible bypass connection at its two ends is integrated into the solar module.

In another development of the present invention, one of the string connections, earth contacts and bypass connections is developed as male plug contact and the other one as female plug contact.

In yet another useful development, the earth and bypass line have a band-type or wire-type conductor in each case, which is also sheathed in a sheath, especially a foil laminate, of the solar module.

The provided photovoltaic array is characterized in that at least a portion of the electrical connections between the solar modules or to an inverter of the array or toward the outside is formed by plug connections.

In one development of the present invention according to this aspect, the array has a first connector piece, which is developed for the electrical connection of a string connection to a bypass connection of one and the same solar module. In another development, which is combinable therewith but also realizable independently, the array has a second connector piece, which is designed for electrically connecting an individual string connection and an earth contact in each case, and optionally of an individual bypass connection of two solar modules connected in series.

A further refinement of the development, which combines the last two aspects, provides that the first and/or the second connector piece are/is developed as generally rigid plastic component having at least one embedded conductor and one connector terminal, which is adapted to the connections of the solar module, at the ends of the individual conductor.

In another useful development, the second connector piece is developed as elongated current bar for the electrical connection and simultaneous support of a plurality of solar modules.

In accordance with the present invention, solar modules are able to connected to each other without the otherwise required separate cables. It is therefore possible to implement especially reliable and simple installations. No cables, plugs, jacks or other devices need to be contacted or produced. An advantage of this type of contacting is the possibility of transferring the functional earthing from module to module. The preferably integrated, additional bypass in the module functions as return conductor and thereby allows an installation that requires no cables whatsoever.

The current bar system according to an above-mentioned development is able to be expanded in a flexible manner for different configurations. An incorrect polarity is able to be avoided by a poka-yoke design of the plug connection. Furthermore, the connection to earth by the potential equalization of the building may be forwarded to all modules via the plug system.

This system additionally offers the advantage that now only one cable having a corresponding single conductor cross-section needs to be routed to the inverter/consumer/battery-charging system. For example, the PV array has to be connected via only one three-pole cable. The individual connection of approximately 24 modules would require the use of 24 individual cables. The insulation of these 24 cables requires a lot of space, which could be drastically reduced by a single cable having three correspondingly sized conductor cross-sections.

A current bar system having a modular design preferably allows a connection of modules in only such a way that the system voltage is always less than 120V DC. This limits the number of modules connected in series. Thus, the entire array has a system voltage of less than 120V DC. Values up to 120V DC are referred to as safety extra-low voltages; these voltages do not endanger lives if current-carrying parts are touched. An array of this type therefore does not pose any danger by electric shock. This may be an especially important aspect for protecting firemen in the event of fires or disasters.

### BRIEF DESCRIPTION OF THE DRAWINGS

Further advantages and advantageous refinements of the subject matters of the present invention are illustrated by the figures and explained in the description below. It should be noted that the figures have only a descriptive character and is not intended to limit the present invention in any form.

FIGS. 1A-1D show schematic illustrations of conventional connection options for solar modules via connection boxes.

FIGS. 2A-2D show different interconnection options of solar modules commonly encountered in practice.

FIG. 3 shows a schematic representation of a solar module according to one specific embodiment of the present invention.

FIG. 4 shows a perspective representation of a solar module according to this specific embodiment of the present invention.

FIG. 5 shows a perspective representation of a connector piece and the abutting region of a solar module according to another development of the present invention.

FIG. 6 shows a schematic representation for elucidating the function of this connector piece.

FIG. 7a shows perspective representation of a connector piece and the adjacent region of a solar module according to another development of the present invention.

FIG. 8 shows a schematic representation for elucidating the function of this connector piece.

FIG. 9 shows a perspective representation of the adjacent edge regions of two solar modules to be connected in series in a roof-integrated system, including a connection profile.

FIG. 10 shows a schematic representation to elucidate the structure of another photovoltaic array.

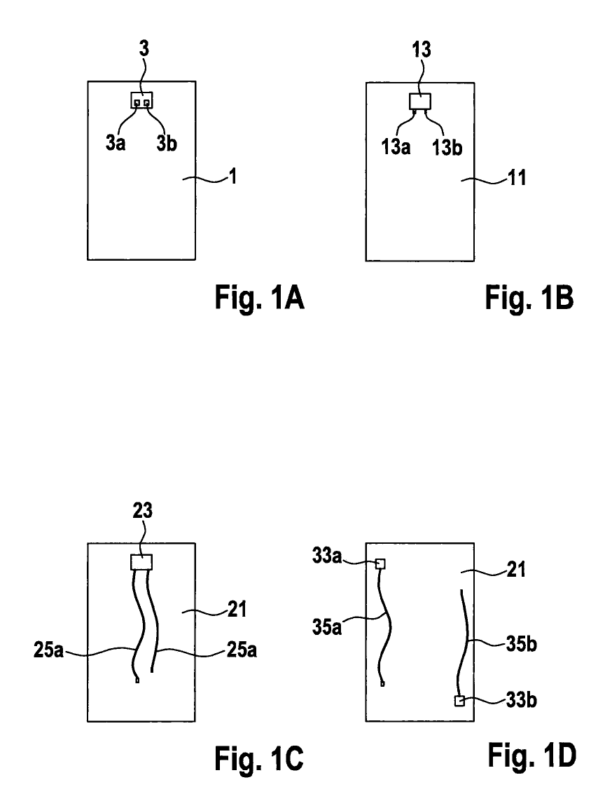

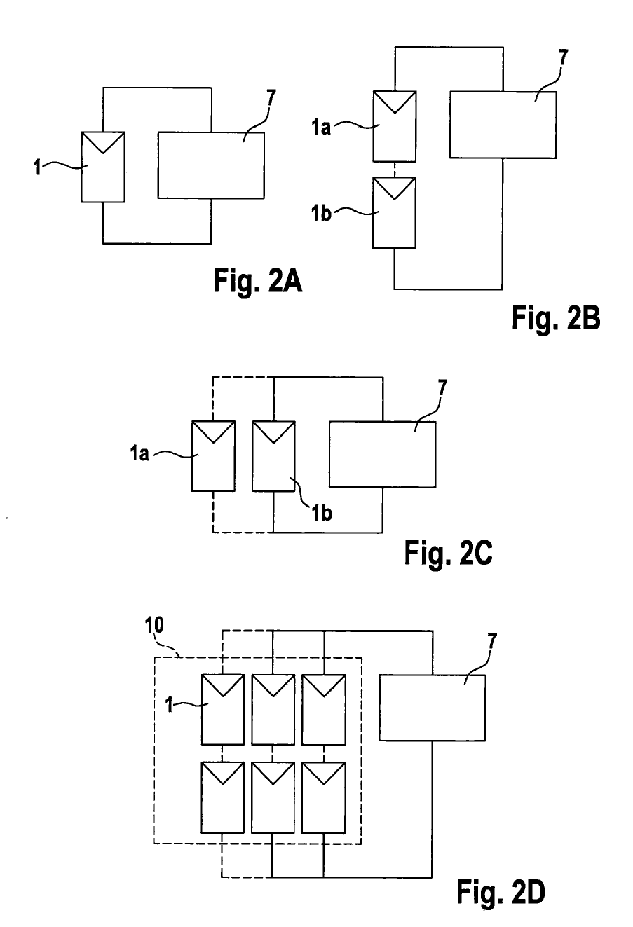

### DETAILED DESCRIPTION OF EXAMPLE EMBODIMENTS

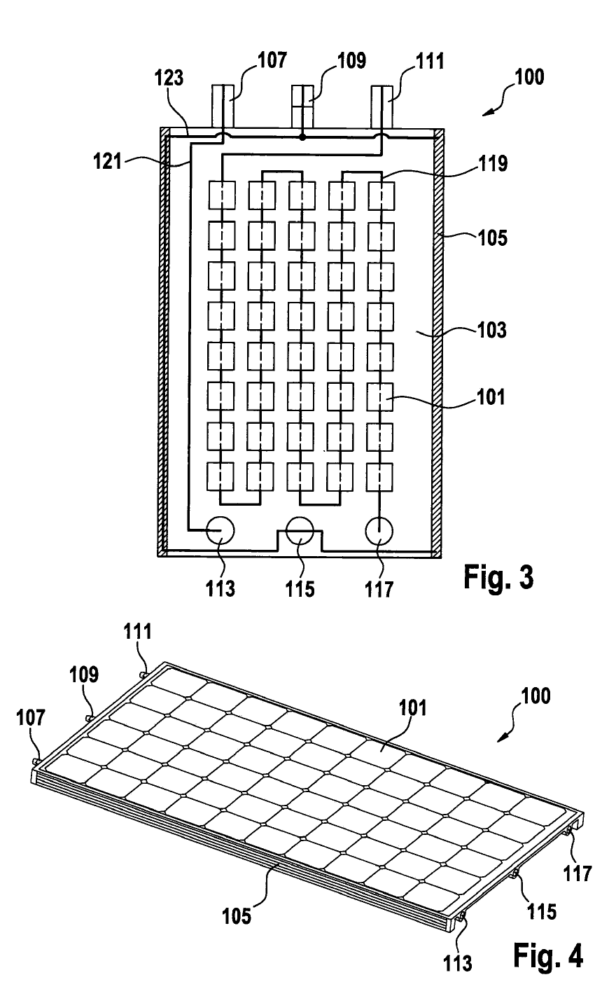

FIG. 3 schematically illustrates a solar module 100 in a plan view, which includes a multitude of solar cells 101 on a substrate 103 and has two conductive frame profiles 105. Three plugs 107 through 111 are provided next to each other on one of the two short edges of solar module 100, i.e., a bypass plug 107, an earth plug 109, and a positive-pole plug 111. Three jacks 113 through 117 are disposed on the opposite short edge of the solar module, in a geometric system that corresponds to said plugs, i.e., a bypass jack 113, an earth contact jack 115, and a negative pole jack 117. Solar cells 101 are interconnected via a first conducting track 119, and positive-pole plug 111 is connected to negative-pole jack 117 (via the solar cells). A second conducting track 121 directly connects bypass plug 107 to bypass jack 113, and a third conducting track 123 constitutes an earth line, which connects earthing plug 109 to earth contact jack 115 together with conductive frame profiles 105.

FIG. 4 shows a constructive development of solar cell 100 in a perspective representation; here, the same reference numerals as in FIG. 3 have been used to denote the main components, but conducting tracks 119 through 123 are not visible.

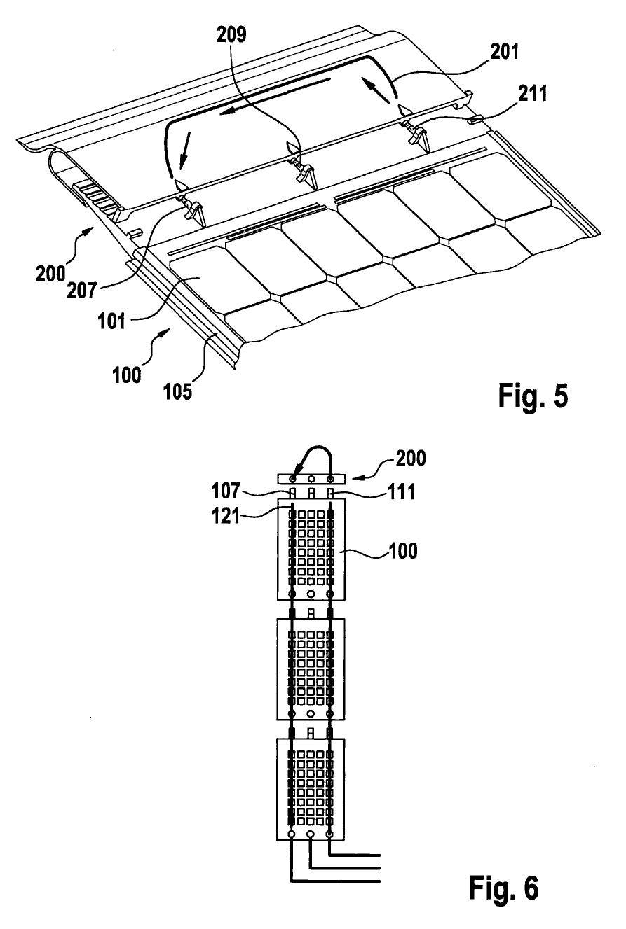

FIG. 5, as a perspective detail view, shows the region of a short edge of solar module 100 with a connector piece 200 mounted thereon, on which three plug components are disposed, which are denoted by numerals 207, 209 and 211, similar to the choice of reference numerals in FIG. 3. Installed between outer plug components 207 and 211, i.e., a bypass plug component and a positive-pole plug component, is a connection cable 201, which has jacks (not denoted specifically) at its ends which match the plugs. The figure also shows another plastic component placed on top of connector piece 200, which is not denoted in the figure and not explained further here.

FIG. 6 schematically illustrates the function of connector piece 200 as upper termination piece in a series connection of three solar modules 100, i.e., the realization of the series connection via the connection of the positive pole of the uppermost solar module to its integrated bypass line 121.

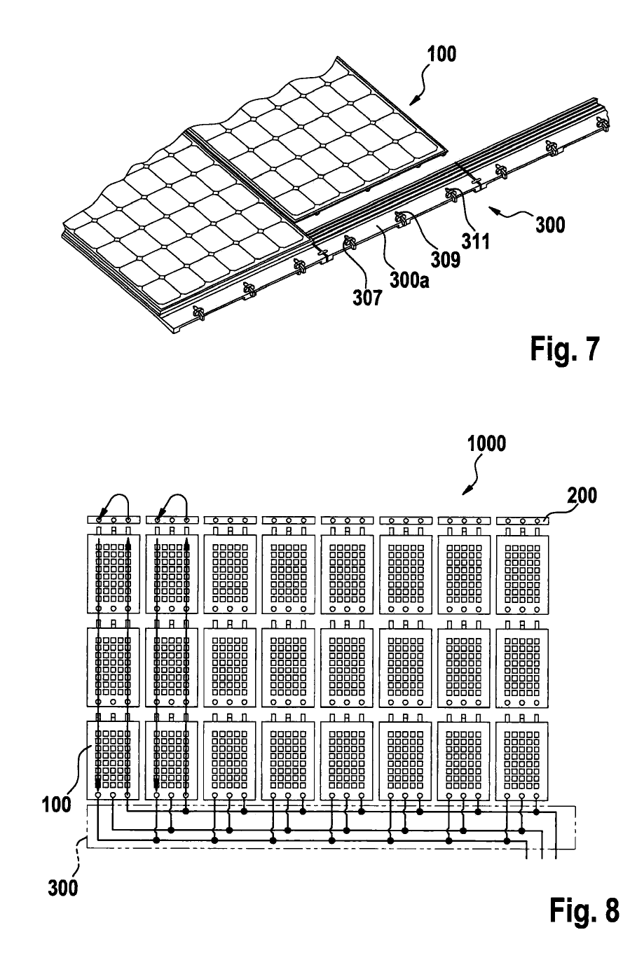

In a perspective representation, FIG. 7 shows the (lower) short sides of two solar modules 100, which are to be interconnected in parallel in a photovoltaic array, together with a connector piece 300, which is composed of a plurality of subsections 300a in the form of an elongated profile, each subsection including a bypass plug component 307, an earth contact plug component 309, and a positive pole plug component 311, similar to profile 200 shown in FIG. 5. These plug components are positioned and developed to engage with the jack components of solar module 100, which are not specifically shown here for reasons of clarity.

FIG. 8 schematically illustrates the placement and internal line routing of connector piece 300 in a photovoltaic array 1000 made up of three rows of eight solar modules 100 connected in parallel to each other. The outputs on the lower right lead to the inverter of the array.

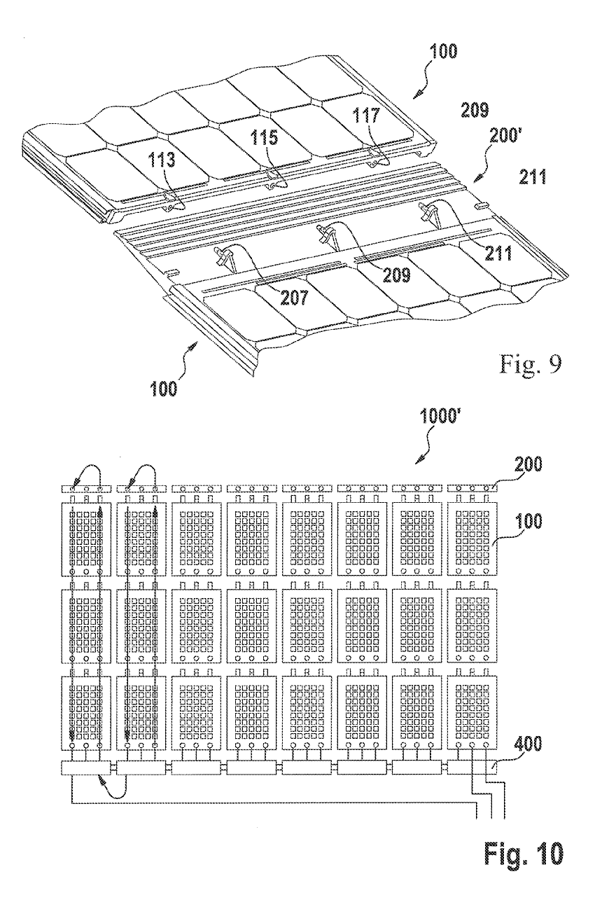

FIG. 9, in another perspective detail view, shows the short sides of two solar modules 100 to be connected in series, together with a connector piece 200′, which is modified in comparison with the development shown in FIG. 5 and differs from connector piece 200 by the omission of the integrated connection cable. When installed, plug components 207, 209 and 211 here engage with correspondingly placed and formed jack components 113, 115 and 117 of the upper solar module, which ultimately causes the positive pole of the lower solar module to be connected to the negative pole of the upper solar module and the earth connections of both solar modules to their bypass connections.

FIG. 10 schematically shows a photovoltaic array 1000′, in which all solar modules 100 are interconnected in series; connector pieces 200 according to FIG. 5 and connector pieces 200′ (not shown here) according to FIG. 9 may be used in addition to additional connector pieces 400, which are situated at the lower edge of the array and may be constructed as current bar system, similar to the configuration according to FIG. 7.

Additional developments and implementations of the exemplarily described method and device result within the actions of one skilled in the art.

What is claimed is:

1. A solar module, comprising:
a plurality of solar cells interconnected in a form of a string, and being externally accessible via two string connections;
wherein the string connections and two earth contacts are plug contacts integrated into the solar module in mechanically fixed manner, and the earth contacts are connected to each other via an earth line integrated into the solar module.

2. The solar module as recited in claim 1, wherein an individual section of the earth lines is formed by a metallic frame part of the solar module.

3. The solar module as recited in claim 2, wherein a bypass line having one externally accessible bypass connection at each of its two ends is integrated into the solar module.

4. The solar module as recited in claim 2, wherein one of the string connections, one of the earth contacts and one of the bypass connections are male plug contacts, and the other one of the string connections, the other one of the earth contacts, and the other one of the bypass connections are female plug contacts.

5. The solar module as recited in claim 3, wherein the earth line and bypass line each include a conductor in the form of one of a band or wire, and the conductor is sheathed in a foil laminate.

6. A photovoltaic array, comprising:
a plurality of solar modules which are electrically connected to each other via electrical connections, at least a portion of the electrical connections between the solar modules being formed by plug connections.

7. A photovoltaic array, comprising:
a plurality of solar modules which are electrically connected to each other, at least a portion of the electrical connections one of: i) to an inverter of the array or ii) outside of the array, is formed by plug connections.

8. The photovoltaic array as recited in claim 6, further comprising:
a first connector piece for electrical connection of a string connection of one of the solar modules of the array to a bypass connection of the same one of the solar modules.

9. The photovoltaic array as recited in claim 6, further comprising:
a second connector piece for electrical connection of a string connection and an earth contact of two adjacently situated solar modules of the array.

10. The photovoltaic array as recited in claim 8, wherein the first connector piece is a rigid plastic component having at least one embedded conductor and one connector-terminal, adapted to connections of the one of the solar modules, at the ends of the conductor.

11. The photovoltaic array as recited in claim 9, wherein the second connector piece is a rigid plastic component having at least one embedded conductor and one connector-terminal, adapted to connections of the two adjacently situated solar modules.

12. The photovoltaic array as recited in claim 11, wherein the second connector piece is an elongated current bar for electrical connection and simultaneous support of a plurality of the solar modules of the array.
